(19) United States
(12) Patent Application Publication
(10) Pub. No.: US 2019/0360330 A1
(43) Pub. Date: Nov. 28, 2019

(54) ENHANCED CAPROCK INTEGRITY INTEGRATION FOR SUBSURFACE INJECTION OPERATIONS

(71) Applicant: CONOCOPHILLIPS COMPANY, Houston, TX (US)

(72) Inventors: Thomas James WHEELER, Houston, TX (US); Nicolas Patrick ROUSSEL, Houston, TX (US)

(21) Appl. No.: 16/422,364

(22) Filed: May 24, 2019

Related U.S. Application Data
(60) Provisional application No. 62/676,074, filed on May 24, 2018.

(51) Int. Cl. E21B 49/00

(52) U.S. Cl. CPC E21B 49/008; G01V 9/00

(57) ABSTRACT

Implementations described and claimed herein provide systems and methods for recovering hydrocarbons from a subterranean formation. In one implementation, at least one drilling operation is executed at the subterranean formation according to at least one drilling parameter. High resolution geomechanical data is continuously captured in-situ during a duration of the at least one drilling operation. A geomechanical model of the subterranean formation is dynamically recalibrated as the high resolution geomechanical data is continuously captured during the at least one drilling operation. An integrity of caprock at the subterranean formation is determined based on the geomechanical model. The at least one drilling parameter is dynamically adjusted based on the integrity of caprock at the subterranean formation.

### CROSS-REFERENCE TO RELATED APPLICATIONS

The present application claims priority to U.S. Provisional Application No. 62/676,074, entitled “Enhanced Caprock Integrity Integration for Subsurface Injection Operations” and filed on May 24, 2018, which is specifically incorporated by reference herein in its entirety.

### BACKGROUND

### I. Technical Field

Aspects of the present disclosure relate generally to systems and methods for recovering hydrocarbons from a subterranean formation and more particularly to providing a robust evaluation of caprock integrity by utilizing high resolution data collected at different times to spatially and temporally set maximum injection operating pressure.

### II. State of the Art

In reservoirs where fluids are injected, caprock integrity is an important yet complex geomechanical issue. This is particularly evident in heavy oil reservoirs where thermal operations are conducted, as significant stress state changes occur throughout the injection/production life. Evaluation and understanding of mechanical properties of caprock are critical to the design of virtually any project involving fluid injection operations (e.g., water, gas, solvent, steam, CO₂, etc). For example, caprock integrity is a driver of success in CO₂ sequestration projects. It is also an integral part in underground storage (e.g. natural gas in salt caverns). In such cases, characterization of geologic and geomechanical properties of the caprock is essential.

Analysis of caprock integrity depends on an integration of disparate data. Conventionally, sparse data (e.g., limited core, mini-frac analysis, Brazilian tensile test on core samples, etc.), collected over limited locations and averaged across the caprock thickness is frequently used to quantify the integrity of caprock. However, such approaches, which are typically conducted on rocks prior to production/injection operations, generally result in a high level of uncertainty when determining caprock integrity. On the other hand, other approaches aimed at decreasing uncertainty often require a suspension of drilling operations to collect data, thereby impacting production and hydrocarbon recovery.

It is with these observations in mind, among others, that various aspects of the present disclosure were conceived and developed.

### SUMMARY

Implementations described and claimed herein address the foregoing problems by providing systems and methods for recovering hydrocarbons from a subterranean formation. In one implementation, at least one drilling operation is executed at the subterranean formation according to at least one drilling parameter. High resolution geomechanical data is continuously captured in-situ during a duration of the at least one drilling operation. A geomechanical model of the subterranean formation is dynamically recalibrated as the high resolution geomechanical data is continuously captured during the at least one drilling operation. An integrity of caprock at the subterranean formation is determined based on the geomechanical model. The at least one drilling parameter is dynamically adjusted based on the integrity of caprock at the subterranean formation.

In another implementation, high resolution geomechanical data corresponding to the subterranean formation is obtained. The high resolution data is captured by a measurement system during a drilling operation at the subterranean formation, and the measurement system includes at least one sensor. The drilling operation includes an injection operation at one or more injection points in the subterranean formation. An initial geomechanical model of the subterranean formation is obtained. An updated geomechanical model of the subterranean formation is generated by recalibrating the initial model with the high resolution geomechanical data. An integrity of caprock at the subterranean formation is determined based on the updated geomechanical model. At least one drilling parameter of the drilling operation is updated based on the integrity of the caprock at the subterranean formation.

Other implementations are also described and recited herein. Further, while multiple implementations are disclosed, still other implementations of the presently disclosed technology will become apparent to those skilled in the art from the following detailed description, which shows and describes illustrative implementations of the presently disclosed technology. As will be realized, the presently disclosed technology is capable of modifications in various aspects, all without departing from the spirit and scope of the presently disclosed technology. Accordingly, the drawings and detailed description are to be regarded as illustrative in nature and not limiting.

### BRIEF DESCRIPTION OF THE DRAWINGS

The foregoing summary, as well as the following detailed description, will be better understood when read in conjunction with the appended drawing. For the purpose of illustration, there is shown in the drawing certain embodiments of the present inventive concept. It should be understood, however, that the present inventive concept is not limited to the precise embodiments and features shown. The accompanying drawing, which is incorporated in and constitutes a part of this specification, illustrates an implementation of apparatuses consistent with the present inventive concept and, together with the description, serves to explain advantages and principles consistent with the present inventive concept, in which:

FIG. 1 illustrates an example system for hydrocarbon recovery from a subterranean formation;

FIG. 2 illustrates example operations for hydrocarbon recovery from a subterranean formation;

FIG. 3 shows example operations for hydrocarbon recovery from a subterranean formation; and

FIG. 4 shows an example computing system that may implement various systems and methods discussed herein.

### DETAILED DESCRIPTION

Aspects of the present disclosure involve systems and methods for recovering hydrocarbons from a subterranean formation. In one aspect, a hydrocarbon production system provides a robust evaluation of caprock integrity by utilizing high resolution data collected at different times to spatially and temporally set maximum injection operating pressure. For example, in oil sands, drillers can drill 30 plus penetrations per square mile before setting horizontal wells. Throughout the production life, drillers can re-drill wells/horizontals and/or add observation wells providing additional data.

The presently disclosed technology provides an enhanced evaluation of caprock integrity. The systems and methods disclosed herein reduce uncertainty associated with caprock integrity calculations by providing higher density data input into a geomechanical model, reducing costs associated with lab and field data gathering, and allowing for updates to the geomechanical model with high resolution data over the life of an injection project. Conventionally, running core tests and mini-frac's are very expensive. The presently disclosed technology can provide a five-fold increase or better for similar cost over conventional approaches. Moreover, the presently disclosed technology allows mechanical properties to be characterized continuously or near-continuously over a depth interval (in both overburden and reservoir).

### I. Terminology

In the description, phraseology and terminology are employed for the purpose of description and should not be regarded as limiting. For example, the use of a singular term, such as “a”, is not intended as limiting of the number of items. Also, the use of relational terms are used in the description for clarity in specific reference to the figure and are not intended to limit the scope of the present inventive concept or the appended claims. Further, any one of the features of the present inventive concept may be used separately or in combination with any other feature. For example, references to the term “implementation” means that the feature or features being referred to are included in at least one aspect of the presently disclosed technology. Separate references to the term “implementation” in this description do not necessarily refer to the same implementation and are also not mutually exclusive unless so stated and/or except as will be readily apparent to those skilled in the art from the description. For example, a feature, structure, process, step, action, or the like described in one implementation may also be included in other implementations, but is not necessarily included. Thus, the presently disclosed technology may include a variety of combinations and/or integrations of the implementations described herein. Additionally, all aspects of the presently disclosed technology as described herein are not essential for its practice.

Lastly, the terms “or” and “and/or” as used herein are to be interpreted as inclusive or meaning any one or any combination. Therefore, “A, B or C” or “A, B and/or C” mean any of the following: “A”; “B”; “C”; “A and B”; “A and C”; “B and C”; or “A, B and C.” An exception to this definition will occur only when a combination of elements, functions, steps or acts are in some way inherently mutually exclusive.

### II. General Architecture and Operations

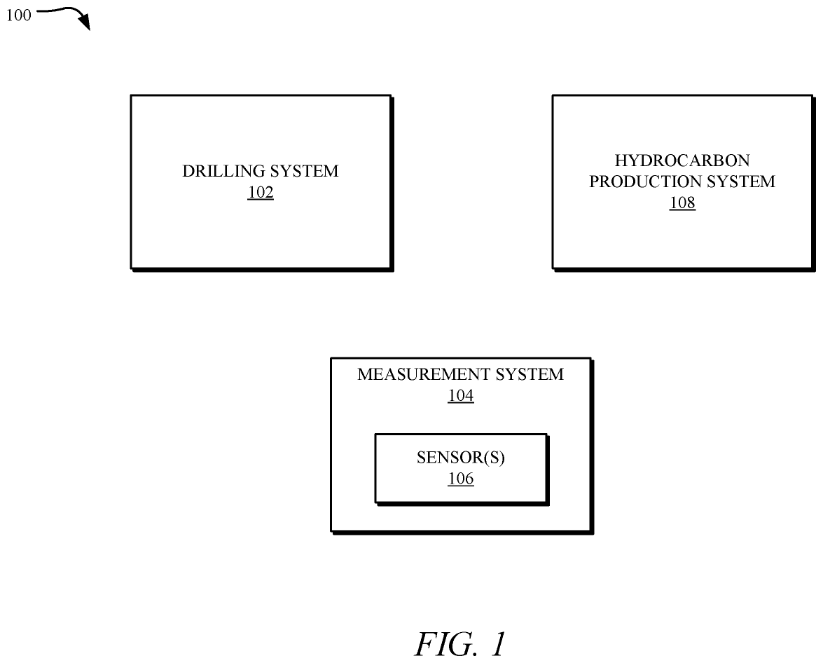

Turning to FIG. 1, in one implementation a system 100 for recovering hydrocarbons from a subterranean formation includes a drilling system 102, a measurement system 104 having one or more sensors 106, and a hydrocarbon production system 108. The one or more sensors 106 may be deployed at the surface and/or subsurface at one or more locations of the subterranean formation.

In one implementation, the drilling system 102 involves a steam assisted gravity drainage (SAGD) system for producing hydrocarbons from the subterranean formation. For example, the drilling system 102 may include two parallel horizontal wells drilled in the formation. An upper well may inject steam, possibly mixed with solvents or other fluids, into the formation, and a lower well, traditionally one about 4 to 6 meters below the upper well, may collect heated crude oil or bitumen that flows out of the formation, along with any water from the condensation of injected steam.

During SAGD projects, understanding caprock integrity allows one to correctly set a maximum injection operating pressure (MOP) for the drilling system 102. MOP can be defined as the maximum pressure allowed to operate a SAGD steam chamber as set by regulations. This value is currently set based on a few mini-frac/diagnostic fracture injection test analysis. In other injection projects, MOP is the maximum operating pressure without failing the rock (fracing). Otherwise, mechanical integrity of caprock can be compromised through significant changes in pore pressure altering stresses in the reservoir and overburden causing tensile fracturing, fault activation and/or bedding plane slip. Typically, operations must be maintained below the MOP to ensure that caprock/overburden failure does not occur during injection and production operations and lead to eventual containment loss.

As such, in one implementation, the measurement system 104 captures high resolution geomechanical data during drilling, and the hydrocarbon production system 108 utilizes this low cost, high resolution data gathered while drilling to continuously populate a numerical geomechanical model. Geomechanical models relate rock mechanical and poroelastic properties (e.g. Young's modulus, Poisson ratio, Biot constant, tensile/compressive strength), formation pore pressure, and the orientation and magnitude of at least one principal stress (e.g., the three principal stresses). This approach gives insight into changing stress and mechanical properties in the caprock/overburden as wells are drilled over development life of a project using the drilling system 102. This can also identify caprock failures that might otherwise go unnoticed. The hydrocarbon production system 108 refines the geomechanical model of the reservoir (e.g., incorporating new data to improve and reduce uncertainty), caprock integrity, and overburden from data collected at multiple times to adjust or otherwise update operating pressures at multiple locations throughout the field. As a result, hydrocarbon recovery is improved while ensuring caprock integrity and containment.

In one implementation, the hydrocarbon production system 108 characterizes geologic and geomechanical properties of caprock during an initial evaluation whenever fluids are injected into a subsurface reservoir using the drilling system 102. Geological analysis involves sedimentological, structural and petrophysical analysis, and interpretation of depositional environment. In many cases, this analysis also involves a detailed understanding of discontinuities such as fractures induced by faulting. Geomechanical characterization provides an understanding of in-situ stresses, rock mechanical properties, and pore pressure in the caprock. A combination of physical laboratory measurements using core, and field tests captures by the measurement system 104 provides data used in this characterization.

Other types of subsurface data, such as, drilling data, seismic data, logs, core and well tests data (mini-fracs) captured by the measurement system 102 can be used to estimate in-situ stress and rock properties using the hydrocarbon production system 108. However, gathering this data is expensive and typically gathered before injection operations have begun. In many cases, data from a single conventional mini-frac (mini-frac test results only consider tensile failure, hence are insufficient to predict the risk of failure of the caprock) and one to two cores may be used in a dynamic 3D model to set the maximum injection pressure for a project. Deposition and rock property variability across a development area may not be adequately described with the limited data used in the geomechanical modeling.

As such, the measurement system 104 captures high density rock mechanics data in a cost effective manner. This data can be gathered without stopping drilling operations. Stated differently, the measurement system 104 captures high density rock mechanics data during drilling of exploration, delineation and development wells, thus allowing for continuous updating of the numerical geomechanical model using the hydrocarbon production system 108.

Subsequent drilling with the drilling system 102, such as infill wells, can provide additional information on effects of transient stresses from injection/depletion which could result in deterioration of caprock strength properties and caprock failure. This mechanical and stress data can be gathered using the measurement system 104 across a large vertical rock section comprising the reservoir and overburden providing insight into vertical variability of the caprock mechanical properties. Inputting this data spatially and in time (e.g., capturing changes in stress state hence changes in mechanical strength of caprock as additional data is collected via additional penetrations over life of an injection operation) into a numerical geomechanical model using the hydrocarbon production system 108 will allow operators insight into the risks associated with caprock failure, reduce the uncertainty of the geomechanical models, and allow operators to set local MOP's for injection based upon the caprock properties and associated failure risk (that is, MOP may be variable across a project in which there are multiple points of injection). This improved model can also be coupled with reservoir simulation helping an operator assess risk with higher or lower injection pressures, impacting project economics. Output of the geomechanical model may include, without limitation, information to set the MOP, such as stress state and failure points, and/or other drilling parameters.

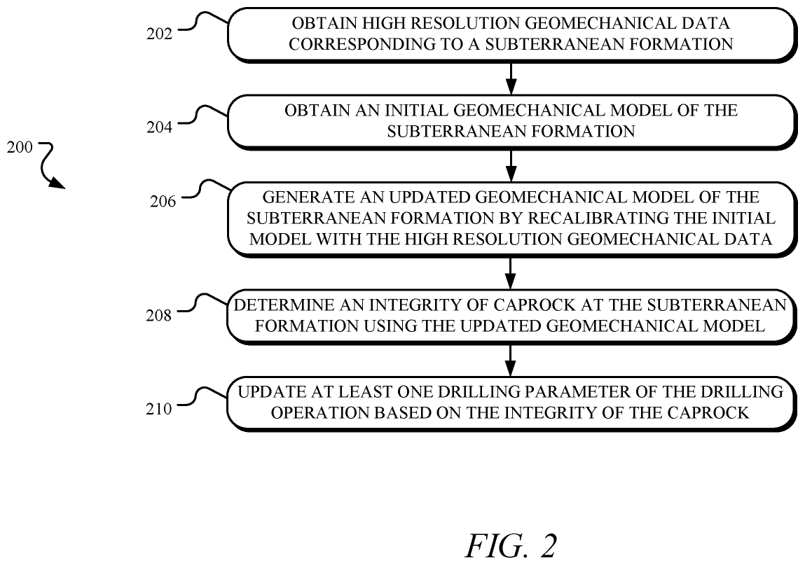

Turning to FIG. 2, example operations 200 for recovering hydrocarbons from a subterranean formation are illustrated. The operations 200 may be executed for example by the hydrocarbon production system 108. In one implementation, an operation 202 obtains high resolution geomechanical data corresponding to the subterranean formation. The high resolution geomechanical data may be captured by a measurement system during a drilling operation at the subterranean formation. The measurement system includes at least one sensor, which may be deployed at the surface and/or at subsurface location(s) of the subterranean formation. The drilling operation may include an injection operation at one or more injection points in the subterranean formation. The injection operation may include a steam assisted gravity drainage injection operation at the injection point(s). However, other injection operations are contemplated.

The high resolution geomechanical data may be captured continuously over a duration of the drilling operation at a plurality of capture times, and the updated geomechanical model may be recalibrated continuously at each of the plurality of capture times with the high resolution geomechanical data. In one implementation, the high resolution geomechanical data is captured across one or more vertical sections of the subterranean formation. The high resolution geomechanical data may include or otherwise be based on drilling data, seismic data, logs, core data, well test data, and/or other data captured by the measurement system.

An operation 204 obtains an initial geomechanical model of the subterranean formation, and an operation 206 generates an updated geomechanical model by recalibrating the initial model with the high resolution geomechanical data. The initial geomechanical model relates a set of physical properties of the subterranean formation, including, without limitation, mechanical properties, poroelastic properties, formation pore pressure, orientation of at least one principal stress, magnitude of at least one principal stress, and/or the like. The updates geomechanical model dynamically models changing stress and mechanical properties of the caprock over a duration of the drilling operation.

An operation 208 determines an integrity of caprock at the subterranean formation based on the updated geomechanical model. An operation 210 updates at least one drilling parameter of the drilling operation based on the integrity of the caprock at the subterranean formation. The drilling parameter may include, for example, a maximum operating pressure of the injection operation. The maximum operating pressure may be set locally for each of the injection point(s) based on the integrity of the caprock at each of the injection point(s).

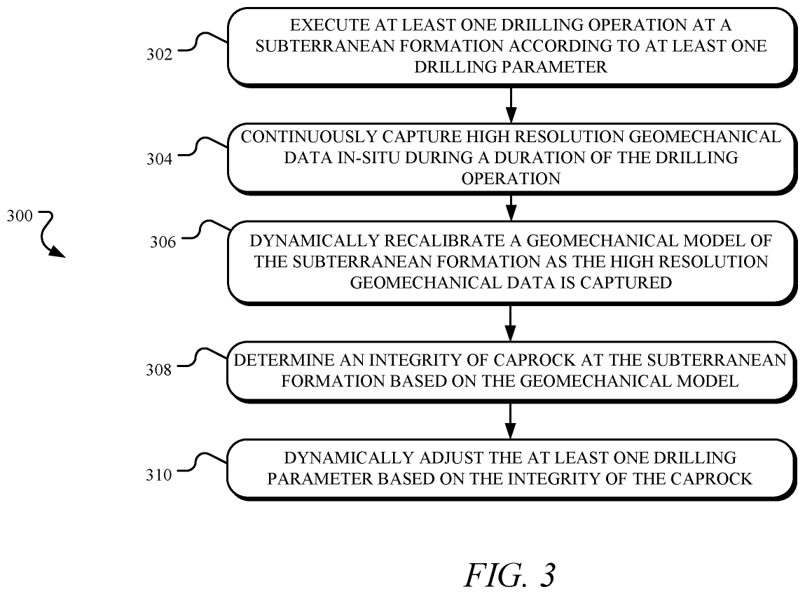

Turning to FIG. 3, example operations 300 for recovering hydrocarbons from a subterranean formation are illustrated. In one implementation, an operation 302 executes at least one drilling operation at the subterranean formation according to at least one drilling parameter. The at least one drilling operation may include a steam assisted gravity drainage injection operation. An operation 304 continuously captures high resolution geomechanical data in-situ during a duration of the at least one drilling operation. The high resolution geomechanical data may be captured without ceasing the at least one drilling operation.

An operation 306 dynamically recalibrates a geomechanical model of the subterranean formation as the high resolution geomechanical data is continuously captured during the at least one drilling operation, and an operation 308 determines an integrity of caprock at the subterranean formation based on the geomechanical model. An operation 310 dynamically adjusts the at least one drilling parameter based on the integrity of caprock at the subterranean formation. The at least one drilling operation may include an injection operation, and the at least one drilling parameter may include a maximum operating pressure of the injection operation. The at least one drilling parameter may be adjusted locally at one or more locations based on the integrity of the caprock at each of the one or more locations.

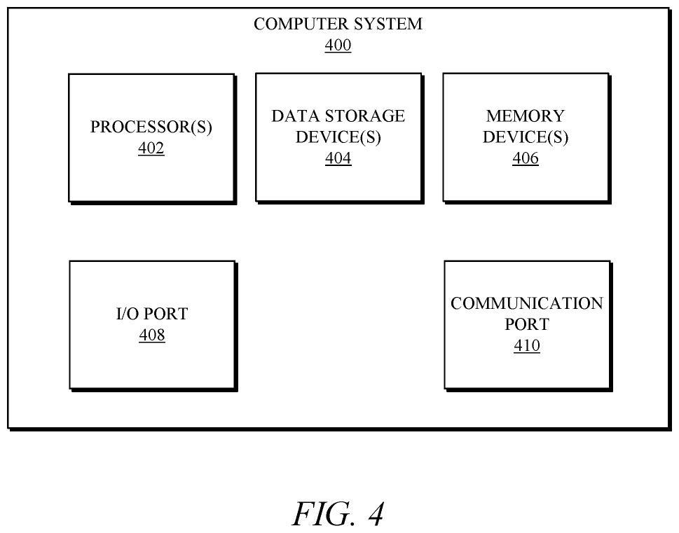

Referring to FIG. 4, a detailed description of an example computing system 400 having one or more computing units that may implement various systems and methods discussed herein is provided. The computing system 400 may be applicable to the drilling system 102, the measurement system 104, the hydrocarbon production system 108, and/or other computing or network devices. It will be appreciated that specific implementations of these devices may be of differing possible specific computing architectures not all of which are specifically discussed herein but will be understood by those of ordinary skill in the art.

The computer system 400 may be a computing system is capable of executing a computer program product to execute a computer process. Data and program files may be input to the computer system 400, which reads the files and executes the programs therein. Some of the elements of the computer system 400 are shown in FIG. 4, including one or more hardware processors 402, one or more data storage devices 404, one or more memory devices 408, and/or one or more ports 408-410. Additionally, other elements that will be recognized by those skilled in the art may be included in the computing system 400 but are not explicitly depicted in FIG. 4 or discussed further herein. Various elements of the computer system 400 may communicate with one another by way of one or more communication buses, point-to-point communication paths, or other communication means not explicitly depicted in FIG. 4.

The processor 402 may include, for example, a central processing unit (CPU), a microprocessor, a microcontroller, a digital signal processor (DSP), and/or one or more internal levels of cache. There may be one or more processors 402, such that the processor 402 comprises a single central-processing unit, or a plurality of processing units capable of executing instructions and performing operations in parallel with each other, commonly referred to as a parallel processing environment.

The computer system 400 may be a conventional computer, a distributed computer, or any other type of computer, such as one or more external computers made available via a cloud computing architecture. The presently described technology is optionally implemented in software stored on the data stored device(s) 404, stored on the memory device(s) 406, and/or communicated via one or more of the ports 408-410, thereby transforming the computer system 400 in FIG. 4 to a special purpose machine for implementing the operations described herein. Examples of the computer system 400 include personal computers, terminals, workstations, mobile phones, tablets, laptops, personal computers, multimedia consoles, gaming consoles, set top boxes, and the like.

The one or more data storage devices 404 may include any non-volatile data storage device capable of storing data generated or employed within the computing system 400, such as computer executable instructions for performing a computer process, which may include instructions of both application programs and an operating system (OS) that manages the various components of the computing system 400. The data storage devices 404 may include, without limitation, magnetic disk drives, optical disk drives, solid state drives (SSDs), flash drives, and the like. The data storage devices 404 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 406 may include volatile memory (e.g., dynamic random access memory (DRAM), static random access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 404 and/or the memory devices 406, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 400 includes one or more ports, such as an input/output (I/O) port 408 and a communication port 410, for communicating with other computing, network, or vehicle devices. It will be appreciated that the ports 408-410 may be combined or separate and that more or fewer ports may be included in the computer system 400.

The I/O port 408 may be connected to an I/O device, or other device, by which information is input to or output from the computing system 400. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 400 via the I/O port 408. Similarly, the output devices may convert electrical signals received from computing system 400 via the I/O port 408 into signals that may be sensed as output by a human, such as sound, light, and/or touch. The input device may be an alphanumeric input device, including alphanumeric and other keys for communicating information and/or command selections to the processor 402 via the I/O port 408. The input device may be another type of user input device including, but not limited to: direction and selection control devices, such as a mouse, a trackball, cursor direction keys, a joystick, and/or a wheel; one or more sensors, such as a camera, a microphone, a positional sensor, an orientation sensor, a gravitational sensor, an inertial sensor, and/or an accelerometer; and/or a touch-sensitive display screen (“touchscreen”). The output devices may include, without limitation, a display, a touchscreen, a speaker, a tactile and/or haptic output device, and/or the like. In some implementations, the input device and the output device may be the same device, for example, in the case of a touchscreen.

The environment transducer devices convert one form of energy or signal into another for input into or output from the computing system 400 via the I/O port 408. For example, an electrical signal generated within the computing system 400 may be converted to another type of signal, and/or vice-versa. In one implementation, the environment transducer devices sense characteristics or aspects of an environment local to or remote from the computing device 400, such as, light, sound, temperature, pressure, magnetic field, electric field, chemical properties, physical movement, orientation, acceleration, gravity, and/or the like. Further, the environment transducer devices may generate signals to impose some effect on the environment either local to or remote from the example computing device 400, such as, physical movement of some object (e.g., a mechanical actuator), heating or cooling of a substance, adding a chemical substance, and/or the like.

In one implementation, a communication port 410 is connected to a network by way of which the computer system 400 may receive network data useful in executing the methods and systems set out herein as well as transmitting information and network configuration changes determined thereby. Stated differently, the communication port 410 connects the computer system 400 to one or more communication interface devices configured to transmit and/or receive information between the computing system 400 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 410 to communicate one or more other machines, either directly over a point-to-point communication path, over a wide area network (WAN) (e.g., the Internet), over a local area network (LAN), over a cellular (e.g., third generation (3G) or fourth generation (4G)) network, or over another communication means. Further, the communication port 410 may communicate with an antenna or other link for electromagnetic signal transmission and/or reception.

In an example implementation, high resolution geomechanical data, geomechanical models, simulations, drilling parameters, and software and other modules and services may be embodied by instructions stored on the data storage devices 404 and/or the memory devices 406 and executed by the processor 402. The computer system 400 may be integrated with or otherwise form part of various components of the system 100.

The system set forth in FIG. 4 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

In the present disclosure, the methods disclosed may be implemented as sets of instructions or software readable by a device. Further, it is understood that the specific order or hierarchy of steps in the methods disclosed are instances of example approaches. Based upon design preferences, it is understood that the specific order or hierarchy of steps in the method can be rearranged while remaining within the disclosed subject matter. The accompanying method claims present elements of the various steps in a sample order, and are not necessarily meant to be limited to the specific order or hierarchy presented.

The described disclosure may be provided as a computer program product, or software, that may include a non-transitory machine-readable medium having stored thereon instructions, which may be used to program a computer system (or other electronic devices) to perform a process according to the present disclosure. A machine-readable medium includes any mechanism for storing information in a form (e.g., software, processing application) readable by a machine (e.g., a computer). The machine-readable medium may include, but is not limited to, magnetic storage medium, optical storage medium; magneto-optical storage medium, read only memory (ROM); random access memory (RAM); erasable programmable memory (e.g., EPROM and EEPROM); flash memory; or other types of medium suitable for storing electronic instructions.

While the present disclosure has been described with reference to various implementations, it will be understood that these implementations are illustrative and that the scope of the present disclosure is not limited to them. Many variations, modifications, additions, and improvements are possible. More generally, embodiments in accordance with the present disclosure have been described in the context of particular implementations. Functionality may be separated or combined in blocks differently in various embodiments of the disclosure or described with different terminology. These and other variations, modifications, additions, and improvements may fall within the scope of the disclosure as defined in the claims that follow.

What is claimed is:

1. A method for recovering hydrocarbons from a subterranean formation, the method comprising:
obtaining high resolution geomechanical data corresponding to the subterranean formation, the high resolution data captured by a measurement system during a drilling operation at the subterranean formation, the measurement system including at least one sensor, the drilling operation including an injection operation at one or more injection points in the subterranean formation;
obtaining an initial geomechanical model of the subterranean formation;
generating an updated geomechanical model of the subterranean formation by recalibrating the initial model with the high resolution geomechanical data;
determining an integrity of caprock at the subterranean formation based on the updated geomechanical model; and
updating at least one drilling parameter of the drilling operation based on the integrity of the caprock at the subterranean formation.

2. The method of claim 1, wherein the high resolution geomechanical data is captured continuously over a duration of the drilling operation at a plurality of capture times.

3. The method of claim 2, wherein the updated geomechanical model is recalibrated continuously at each of the plurality of capture times with the high resolution geomechanical data.

4. The method of claim 2, wherein the high resolution geomechanical data is captured across one or more vertical sections of the subterranean formation, the one or more vertical sections including a hydrocarbon reservoir from which the hydrocarbons are recovered.

5. The method of claim 1, wherein the injection operation includes a steam assisted gravity drainage injection operation at the one or more injection points.

6. The method of claim 1, wherein high resolution geomechanical data is based on at least one of drilling data, seismic data, logs, core data, or well test data.

7. The method of claim 1, wherein the initial geomechanical model relates a set of physical properties of the subterranean formation.

8. The method of claim 7, wherein the set of physical properties includes one or more of mechanical properties, poroelastic properties, formation pore pressure, orientation of at least one principal stress, and magnitude of at least one principal stress.

9. The method of claim 1, wherein the updated geomechanical mdoel dynamically models changing stress and mechanical properties of the caprock over a duration of the drilling operation.

10. The method of claim 1, wherein the at least one drilling parameter includes a maximum operating pressure of the injection operation.

11. The method of claim 10, wherein the maximum operation pressure is set locally for each of the one or more injection points based on the integrity of the caprock at each of the one or more injection points.

12. The method of claim 1, wherein the at least one sensor is deployed at one or more subsurface locations in the subterranean formation.

13. A system for recovering hydrocarbons from a subterranean formation, the system comprising:
a drilling system executing at least one drilling operation at the subterranean formation according to at least one drilling parameter;
a measurement system deployed at the subterranean formation and including at least one sensor, the measurement system continuously capturing high resolution geomechanical data in-situ during a duration of the at least one drilling operation; and
a hydrocarbon production system dynamically recalibrating a geomechanical model of the subterranean formation as the high resolution geomechanical data is continuously captured during the at least one drilling operation, the hydrocarbon production system dynamically adjusting the at least one drilling parameter based on an integrity of caprock at the subterranean formation, the integrity of the caprock determined based on the geomechanical model.

14. The system of claim 13, wherein the at least one drilling operation includes an injection operation and the at least one drilling parameter includes a maximum operating pressure of the injection operation.

15. The system of claim 13, wherein the at least one drilling parameter is adjusted locally at one or more locations based on the integrity of the caprock at each of the one or more locations.

16. The system of claim 13, wherein the at least one drilling operation includes a steam assisted gravity drainage injection operation.

17. A method for recovering hydrocarbons from a subterranean formation, the method comprising:
executing at least one drilling operation at the subterranean formation according to at least one drilling parameter;
continuously capturing high resolution geomechanical data in-situ during a duration of the at least one drilling operation;
dynamically recalibrating a geomechanical model of the subterranean formation as the high resolution geomechanical data is continuously captured during the at least one drilling operation;
determining an integrity of caprock at the subterranean formation based on the geomechanical model; and
dynamically adjusting the at least one drilling parameter based on the integrity of caprock at the subterranean formation.

18. The method of claim 17, wherein the at least one drilling operation includes an injection operation and the at least one drilling parameter includes a maximum operating pressure of the injection operation.

19. The method of claim 17, wherein the at least one drilling parameter is adjusted locally at one or more locations based on the integrity of the caprock at each of the one or more locations.

20. The method of claim 17, wherein the high resolution geomechanical data is captured without ceasing the at least one drilling operation.
